(19) United States
(12) Patent Application Publication
(10) Pub. No.: US 2025/0022815 A1
(43) Pub. Date: Jan. 16, 2025

(54) RF MODULE

(71) Applicant: Infineon Technologies AG, Neubiberg (DE)

(72) Inventors: Ernst SELER, München (DE); Josef KULMER, Graz (AT)

(21) Appl. No.: 18/759,435

(22) Filed: Jun. 28, 2024

(30) Foreign Application Priority Data
Jul. 10, 2023 (DE) 102023206549.5

(51) Int. Cl. H01L 23/66; H01P 5/18; H01Q 1/22; H01Q 5/55

(52) U.S. Cl. CPC H01L 23/66; H01P 5/181; H01Q 1/2275; H01Q 5/55; H01L 2223/6616; H01L 2223/6627; H01L 2223/665

(57) ABSTRACT

An RF module comprises a circuit board, a waveguide antenna, first and second semiconductor circuit devices, and first, second, and third RF ports. The first semiconductor circuit device including a local oscillator to generate a local oscillator signal. The circuit board includes a first opening between the first RF port and a first waveguide port for transferring the local oscillator signal from the first RF port into the first hollow waveguide. The circuit board includes a second opening between the second RF port and a second waveguide port to receive the local oscillator signal from the first hollow waveguide. The second semiconductor circuit device is configured to process a first RF signal based on the received local oscillator signal. The circuit board includes a third opening for transferring the first RF signal between the third RF port and a third waveguide port.

### CROSS-REFERENCE TO RELATED APPLICATION

This application claims priority to Germany Patent Application No. 102023206549.5 filed on Jul. 10, 2023, the content of which is incorporated by reference herein in its entirety.

### TECHNICAL FIELD

The present disclosure relates to RF modules having multiple semiconductor circuit devices.

### BACKGROUND

RF systems which utilize semiconductor circuit devices are used in many mm-wave applications such as such as FMCW radar or 5G mobile communication. Monolithic microwave integrated circuits, MMICs, are semiconductor circuit devices which typically include RF circuitry to implement multiple transmit (TX) channels and/or receive (RX) channels. Furthermore, to allow MIMO operations or Phased antenna array operations, it is desired to increase the number of transmit (TX) channels or receive (RX) channels in order to transmit and/or receive signals over an increased number of antennas. To achieve an antenna array with multiple antennas, implementations make use of arranging the antennas on the printed circuit board. However, manufacturing costs are increased for such solutions as antenna arrays on a printed circuit board require one or more specific layers to reduce the RF loss of the RF transmission signals in the microwave region above 20 GHZ. Furthermore, implementations are known in which antennas are provided within each package of the semiconductor circuit devices or directly on each semiconductor chip. However, specific packages may be required increasing the costs and space limitations may limit the number of antennas which may increase the number of MMICs required for a certain number of antennas. It is therefore desirable to provide an RF module which allows a high performant antenna array operation at reduced manufacturing costs.

### SUMMARY

According to an example, an RF module includes a circuit board including a plurality of signal lines and a waveguide antenna arranged on a first side of the circuit board, the waveguide antenna including a body, an antenna element formed in the body, a first hollow waveguide formed in the body, and a second hollow waveguide formed in the body, wherein the second hollow waveguide is coupled to the antenna element.

A first semiconductor circuit device is arranged on a second side of the printed circuit board and electrically connected to a first signal line of the plurality of signal lines. A second semiconductor circuit device is arranged on the second side of the printed circuit board and electrically connected to a second signal line of the plurality of signal lines.

The RF module includes a first RF port associated with the first semiconductor circuit device, wherein the first semiconductor circuit device includes a local oscillator to generate a local oscillator signal, wherein the circuit board includes a first opening between the first RF port and a first waveguide port associated with the first hollow waveguide for transferring the local oscillator signal from the first RF port into the first hollow waveguide.

The RF module includes a second RF port associated with the second semiconductor circuit device and the circuit board includes a second opening between the second RF port and a second waveguide port associated with the first waveguide to receive the local oscillator signal from the first hollow waveguide. The second semiconductor circuit device is configured to process a first RF signal based on the received local oscillator signal.

The RF module includes a third RF port associated with the second semiconductor circuit device and herein the circuit board includes a third opening for transferring the first RF signal between the third RF port and a third waveguide port associated with the second hollow waveguide.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A and 1B illustrate an example of an RF module.

FIGS. 2A and 2B illustrate a another example of an RF module.

FIGS. 3A and 3B illustrate a another example of an RF module.

FIG. 4 illustrates an example of an RF port.

FIGS. 5A to 5G illustrate a further example of an RF port.

FIG. 6A illustrates an example of a waveguide splitter.

FIG. 6B illustrates an example of a transmission adaption element.

FIGS. 7A, 7B, and 7C illustrate examples of an LO distribution.

### DETAILED DESCRIPTION

The examples described herein provide a new concept for an RF module which utilizes a waveguide antenna. In addition to providing hollow waveguides within the waveguide antenna for transferring RF signals from RF ports of the MMICs to antenna radiation structures, the waveguide antenna further provides a hollow waveguide for transferring a local oscillator (LO) signal generated at one semiconductor circuit device to a further semiconductor circuit device for synchronization.

Therefore, a compact, cost-effective and high performant RF module is provided with the proposed concept. The waveguide antenna can be manufactured utilizing plastic material and molding processes at reduced costs compared to existing RF modules. Furthermore the waveguide antenna allows achieving a synchronization of the semiconductor circuit devices by utilizing the local oscillator signal distributed via the hollow waveguide from one semiconductor circuit device to another semiconductor circuit device. Similar hollow waveguide shapes can be used for the distribution of the LO signal and for the transferring of the transmit or receive signals which makes designing of the additional LO distribution waveguide effortless. Compared to existing solutions, which require the local oscillator signal to be distributed via signal lines on the printed circuit board (PCB), the new concept is capable to distribute the local oscillator signal without down-converting and up-converting as the LO signal is in the same frequency range as the transmit and receive signals. This makes it very attractive for applications which require a processing of RF signals in the microwave region above 60 GHz. Existing solutions required either specific layers on the printed circuit board adapted to a low loss transmission at such high frequencies or a down-conversion of the local oscillator signal prior to the LO signal transmission followed by an up-conversion after the reception of the LO signal at the other semiconductor circuit device. Distinguished therefrom, the new concept achieves a local oscillator signal distribution also in high frequency microwave regions above 60 GHz without down-conversion and up-conversion utilizing waveguide structures within the waveguide antenna. Accordingly, no additional components such as high frequency layers are required.

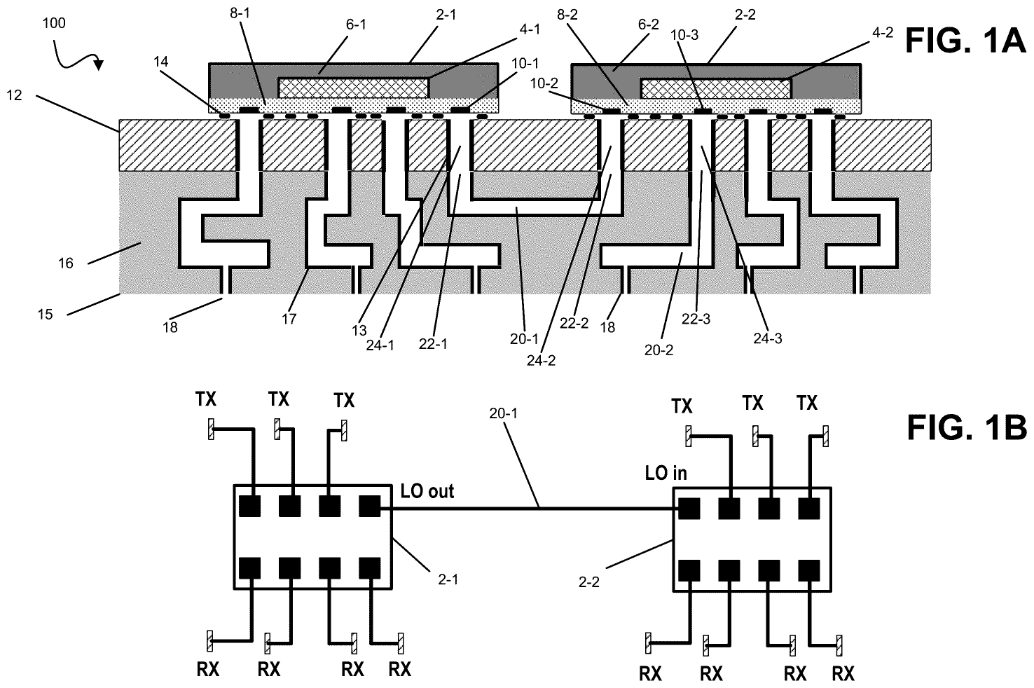

Referring now to FIG. 1A, a first example of an RF module 100 is described. The RF Module 100 comprises a printed circuit board 12, a first semiconductor circuit device 2-1 and a second semiconductor circuit device 2-2. The first semiconductor circuit device 2-1 includes a first semiconductor chip 4-1 and the second semiconductor circuit device 2-2 includes a second semiconductor chip 4-2. The first semiconductor circuit device 2-1 includes a package formed by a molded portion 6-1 and a redistribution layer 8-1. The second semiconductor circuit device 2-2 includes a package formed by a molded portion 6-2 and a redistribution layer 8-2. Molded portions 6-1 and 6-2 may be formed by a molding process using mold material. Molded portions 6-1 and 6-2 extend lateral to the first semiconductor chip 4-1 and second semiconductor chip 4-2, respectively, to form respective fan-out areas. The redistribution layers 8-1 and 8-2 may each comprise one or more metal layers and one or more insulating layers to route signals transferred to the respective semiconductor chips or from the respective semiconductor chips. The redistribution layers 8-1 and 8-2 may be formed by laminating layers. The respective molded portions and redistribution layers may form a fan-out waver level package such as an embedded Wafer Level Ball Grid Array (eWLB).

The first semiconductor circuit device 2-1 and the second semiconductor circuit device 2-2 are mounted on a first side of the printed circuit board 12 and are electrically and mechanically connected to the printed circuit board 12 via external contacts 14. The external contacts 14 may be solder balls, copper pillars or any other structures which can be used for mounting semiconductor circuit devices onto printed circuit boards. Although only two semiconductor circuit devices are shown in FIG. 1A, it is to be noted that more than two semiconductor circuit devices may be mounted on the printed circuit board 12 depending on the required application.

The printed circuit board 12 comprises a plurality of signal lines which may include power supply signal lines coupling the first semiconductor circuit device 2-1 and the second semiconductor circuit device 2-2 to a power supply device, respectively. The printed circuit board 12 may further comprise data signal lines coupling the first semiconductor circuit device 2-1 and the second semiconductor circuit device 2-2 to a processor device mounted on the printed circuit board 12. The printed circuit board 12 may further comprise isolating material such as FR4 material.

The first semiconductor circuit device 2-1 and second semiconductor circuit device 2-2 may be monolithic microwave integrated circuit (MMIC) devices. The first semiconductor circuit device 2-1 and the second semiconductor circuit device 2-2 may each include circuitry to process RF signals. To be more specific, the first semiconductor circuit device 2-1 and the second semiconductor circuit device 2-2 may each include a plurality of transmit (TX) channels and a plurality of receive (RX) channels. Each of the first semiconductor circuit device 2-1 and the second semiconductor circuit device 2-2 may include RF circuitry such as phase shifters, power amplifiers, RF couplers, RF mixers and digital processing circuitry such as digital processors, digital filters, digital Fourier transformation circuitry or Goertzel filters. At least the first semiconductor circuit device 2-1 may further include RF signal generation circuitry, such as a local oscillator, to generate a local oscillator (LO) signal. In one example, the first semiconductor circuit device 2-1 and second semiconductor circuit device 2-2 may be FMCW radar MMIC devices operating in a frequency range above 20 GHZ, for example in the ISM Band, the Ultra Wide (UWB) Band the automotive Long Range Radar (LRR) Band or the Automotive Short Range Radar (SRR) Band. In such implementations, the local oscillator of the first semiconductor circuit device 2-1 may generate frequency modulated RF signals including a plurality of chirps (also know as frequency ramps). According to examples described herein, the first semiconductor circuit device 2-1 and second semiconductor circuit device 2-2 may form a cascaded system or may be part of a cascaded system. The first semiconductor circuit device 2-1 may be considered in the cascaded system as a primary device since the device generates the LO signal and the second semiconductor circuit device 2-2 may be considered a secondary device since the second semiconductor circuit device 2-2 receives the LO signal from the first semiconductor circuit device 2-1 and utilizes the LO signal to process RF signal, for example to generate an RF transmit signal or to demodulate a received RF signal. The transmission of the LO signal from the first semiconductor circuit device 2-1 to the second semiconductor circuit device 2-2 allows the synchronization of the RF processing. It is to be noted that a MIMO operations may require a predetermined phase relation of the RF signals transmitted or received. As RF signals are processed in multiple semiconductor circuit devices, the concept of generating one LO signal in one semiconductor circuit device and transmitting the signal to the other semiconductor circuit devices for RF processing may establish the required phase relation.

The RF module 100 further comprises a waveguide antenna 15 including a body 16 and hollow waveguides formed in cavities inside the body 16. The waveguide antenna 15 is mounted at a first side of the body 16 to the printed circuit board 12 such that the printed circuit board 12 is between the waveguide antenna 15 and the semiconductor circuit devices 2-1 and 2-2. The waveguide antenna 15 includes multiple antennas for providing an antenna array as will be described later. The body 16 of the waveguide antenna 15 may comprise plastic material and may be formed using molding techniques or other manufacturing methods. The hollow waveguides are formed by metal surfaces 17 of the cavities inside the body 16. The body 16 may be a single part or may be formed by mounting two or more parts of the body 16 together. Mounting of the parts may include screwing, gluing, soldering or other methods of mounting. The waveguide antenna 15 further includes receive and/or transmit antennas formed by antenna elements 18. Antenna elements 18 may be configured to transmit RF signals external to the RF module or receive RF signals from external. Each of the antenna elements 18 may include one or more slots formed at a second side of the body 16 such that slot antennas are formed by the antenna elements 18. The antenna elements 18 may form an antenna array for providing MIMO operation of the RF module 100 such that RF signals are transmitted by multiple antennas external to the RF module 100 and RF signals are received from external of the RF module 100 by multiple antennas. Each of the antennas is associated with one or more respective RF channels in one of the first semiconductor circuit device 2-1 or second semiconductor circuit device 2-2. In some examples an antenna may be associated with one RF channel while in other examples an antenna may be associated with multiple RF channels.

The waveguide antenna 15 includes a first hollow waveguide 20-1 for transferring the LO signal from the first semiconductor circuit device 2-1 to the second semiconductor circuit device 2-2. Since the LO signal distribution is provided for synchronizing the RF processing in the first semiconductor circuit device 2-1 with the second semiconductor circuit device 2-2, the first hollow waveguide 20-1 may also be referred to as a synchronization waveguide.

The RF module 100 has a first waveguide port 22-1 associated with the first hollow waveguide 20-1 and a second waveguide port 22-2 associated with the first hollow waveguide. The first waveguide port 22-1 and second waveguide port 22-2 are arranged in the waveguide antenna 15 and may in one example be a first end and a second end of the hollow waveguide or may be coupled to a first end and a second end of the first hollow waveguide 20-1.

A first opening 24-1 is formed in the printed circuit board 12 such that the first opening 24-1 is between a first RF port 10-1 associated with the first semiconductor circuit device 2-1 and the first waveguide port 22-1. The first RF port 10-1, the first opening 24-1 and the first waveguide port 22-1 are configured to allow the coupling of the LO signal from the first semiconductor circuit device 2-1 into the first hollow waveguide 20-1. A second opening 24-2 is formed in the printed circuit board 12 such that the second opening 24-2 is between a second RF port 10-2 associated with the second semiconductor circuit device 2-2 and the second waveguide port 22-2. Metal walls 13 may be formed on sidewalls of the printed circuit board 12 associated with the openings 24-1 and 24-2. The second RF port 10-2, the second opening 24-2 and the second waveguide port 22-2 are configured to allow the coupling of the LO signal from the first hollow waveguide 20-1 into the second semiconductor circuit device 2-2. As shown in FIG. 1A, the RF ports 10-1 and 10-2 extend in a respective fan-out area of the first semiconductor circuit device 2-1 and second semiconductor circuit device 2-2. As shown in FIG. 1A, the first hollow waveguide 20-1 may have vertical portions extending perpendicular to a main surface of the body 16 and one or more lateral portions extending parallel to the main surface of the body 16.

As explained above, the second semiconductor circuit device 2-2 uses the LO signal received from the first semiconductor circuit device 2-1 to process a first RF signal. To be more specific, the LO signal is used to generate an RF transmit signal or to generate a baseband signal by supplying the LO signal to a mixer and mixing the LO signal with a received RF signal.

The RF module 100 includes a third RF port 10-3 associated with the second semiconductor circuit device 2-2 and the printed circuit board 12 includes a third opening 24-3 for transferring the first RF signal between the third RF port 10-3 and a third waveguide port 22-3 associated with a second hollow waveguide 20-2. The second hollow waveguide 20-2 is formed in the body 16 and couples the third waveguide port 22-3 to the respective antenna element 18. In case the third RF port 10-3 is a receive RF port, the first RF signal is received from the respective antenna element 18 via the second hollow waveguide 20-2 and the third waveguide port 22-3. In case the first RF port 10-3 is a transmit RF port, the first RF signal is transmitted from the third RF port 10-3 via the third waveguide port 22-3 and the second hollow waveguide 20-2 to the respective antenna element 18.

The first hollow waveguide 20-1 and the second hollow waveguide 20-2 can be rectangular waveguides having a rectangular cross-section or can be circular or ellipsoid-shaped waveguides having a circular or ellipsoid cross-section. The first hollow waveguide 10-1 and the second hollow waveguide 10-2 may be configured for transmission in a TE mode or a TM mode. In examples, the first hollow waveguide 10-1 and the second hollow waveguide 10-2 may have a same cross-section shape and a same cross-section area since the signals transferred in the first hollow waveguide 10-1 and the second hollow waveguide 10-2 may have a same frequency or are in the same frequency range. This allows implementing the LO distribution in the waveguide antenna without any specific design changes for the hollow waveguides provided in the body 16.

It is further noted that the first semiconductor circuit device 2-1 and the second semiconductor circuit device 2-2 may have additional RF ports which are coupled in the same manner as described above to respective antenna elements 18. FIG. 1B shows schematically one example in which each of the first semiconductor circuit device 2-1 and the second semiconductor circuit device 2-2 has 3 transmit channels and 4 receive channels which are coupled to respective antenna elements via hollow waveguides as described above. Accordingly, the RF system of FIG. 1B implements a MIMO system with 6 transmit and 8 receive channels in which each of the transmit and receive channel is based on the LO signal generated in the first semiconductor circuit device 2-1. FIG. 1 shows the distribution of the LO signal from the first semiconductor circuit device 2-1 to the second semiconductor circuit device 2-2 via the first hollow waveguide 20-1 and the transfer of the transmit and receive signals via respective second hollow waveguides.

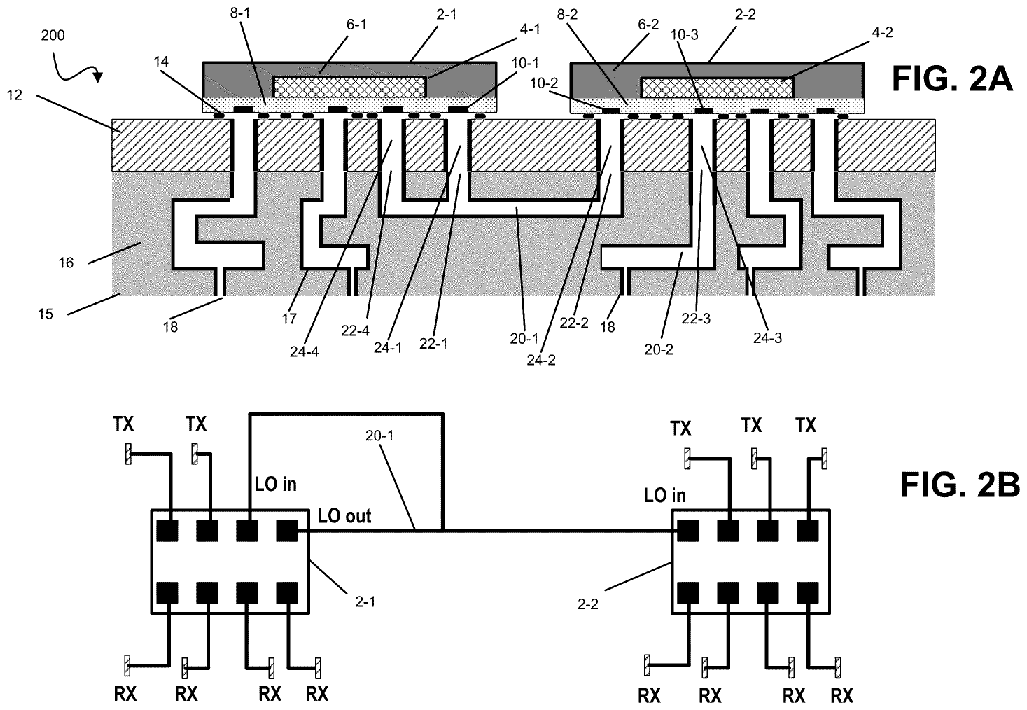

Referring now to FIGS. 2A and 2B a further example of an RF module 200 will be described. Distinguished from the example described with respect to FIGS. 1A and 1B, the RF module 200 comprises a self-feeding of the LO signal back to the first semiconductor circuit device 2-1. To this end, the first hollow waveguide 20-1 is split in a first part and a second part. The first part is coupled to the second waveguide port 22-2 to transfer the LO signal via the second waveguide port 22-2 and the second opening 24-2 to the RF port 10-2 as described above. The second part is coupled to a fourth waveguide port 22-4 associated with the first semiconductor circuit device 2-1. A fourth opening 24-4 is provided in the printed circuit board 12 in order to transfer the LO signal transmitted in the second part of the first hollow waveguide 20-1 to an RF port associated with the first semiconductor circuit device 2-1. In the first semiconductor circuit device 2-1, the LO signal received from the second part of the first hollow waveguide 20-1 is then transferred to the first semiconductor chip 4-1. Rather than using directly the LO signal generated in the first semiconductor chip 4-1, the first semiconductor chip 4-1 uses the LO signal fed back via the second part of the first hollow waveguide 20-1 to process RF signals, e.g., to generate a transmit signal or to down-convert a receive signal. The feedback of the LO signal allows to obtain a synchronization of the receive and transmit channels in the semiconductor circuit devices 2-1 and 2-2 in a more stable manner. Temperature variations cause changes in the length of hollow waveguides which may lead in the example of FIGS. 1A and 1B to relative phase changes of the LO signal used in the first semiconductor circuit device 2-1 and the second semiconductor circuit device 2-2. In the example of FIG. 2A, the LO signal transferred to the second semiconductor circuit device 2-2 and the LO signal transferred to the first semiconductor circuit device 2-1 are affected in a same manner and therefore relative phases are compensated or reduced. In some examples, in the first hollow waveguide 20-1 the length from the first waveguide port 22-1 to the second waveguide port 22-2 is the same as the length from the first waveguide port 22-1 to the fourth waveguide port 22-4 making the distribution of the LO signal to both waveguide ports symmetric. Other features of the RF module 200 are similar to the RF module 100 and reference is made to the description of FIG. 1A.

FIG. 2B shows schematically the RF module 200 implementing LO feedback. Compared to the RF module 100 shown in FIG. 1B, the RF module 200 has one receive channel less as the corresponding RF port is now used for receiving the LO signal fed back to the first semiconductor circuit device 2-1. However, in other implementations dedicated LO signal ports may be used for transferring and receiving the LO signal in which the feedback of the LO signal may not reduce the number of RF channels.

Referring now to FIGS. 2A and 2B a further example of an RF module 300 will be described.

Instead of generating the LO signal in a MMIC comprising RF channels, the first semiconductor circuit device 2-1 is implemented in the RF module 300 as a dedicated LO generation device. The LO signal generated in the first semiconductor circuit device 2-1 is then transferred via a first part of the first hollow waveguide 20-1 to the second waveguide port 22-2 and via the second opening 24-2 to the second RF port 10-2 associated with the second semiconductor circuit device 2-2. Furthermore, the LO signal generated in the first semiconductor circuit device 2-1 is transferred via a second part of the first hollow waveguide 20-1 to the fourth waveguide port 22-4 and via the fourth opening 24-4 to the fourth RF port 10-2 associated with the third semiconductor circuit device 2-3. The second semiconductor circuit device 2-2 and the third semiconductor circuit device 2-3 are implemented as MMICs having RF channels, e.g., RF receive channels or RF transmit channels. The LO signal is used in the second semiconductor circuit device 2-2 and the third semiconductor circuit device 2-3 to process RF signals as described above. In some examples, in the first hollow waveguide 20-1 the length from the first waveguide port 22-1 to the second waveguide port 22-2 is the same as the length from the first waveguide port 22-1 to the fourth waveguide port 22-4 making the distribution of the LO signal to both waveguide ports symmetric. Other features of the RF module 200 are similar to the RF module 100 and RF module 300 and reference is made to the description of FIGS. 1A and 1B.

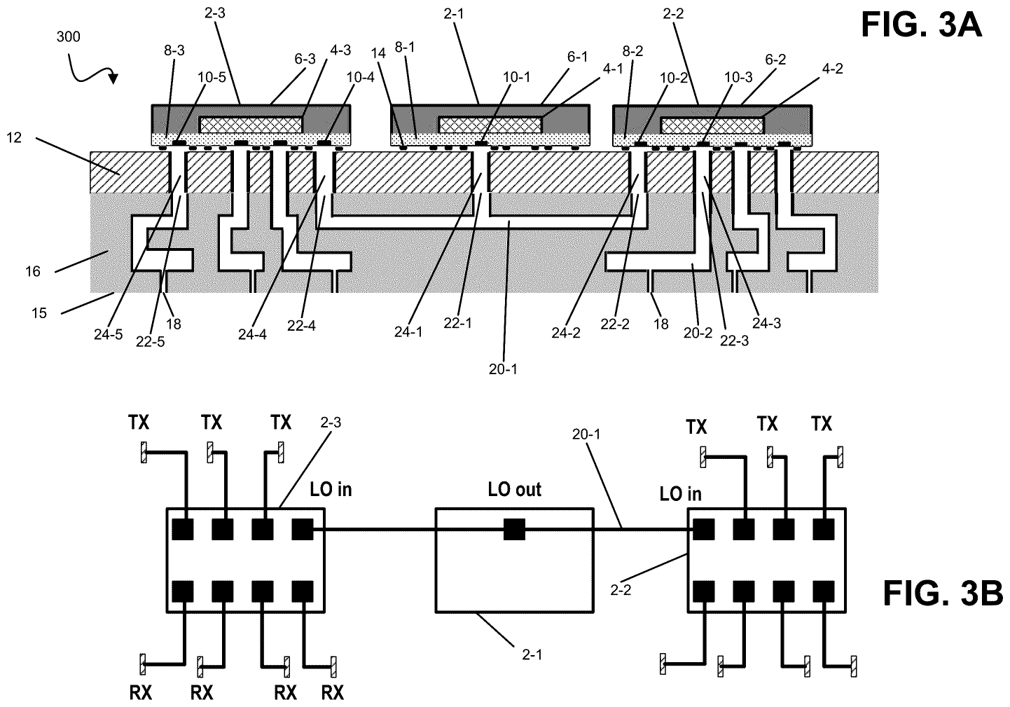

FIG. 3B shows schematically the LO distribution of the RF module 300 with the first semiconductor circuit device 2-1 distributing the LO signal symmetric to the second semiconductor circuit device 2-2 and third semiconductor circuit device 2-3 via the first hollow waveguide 20-1.

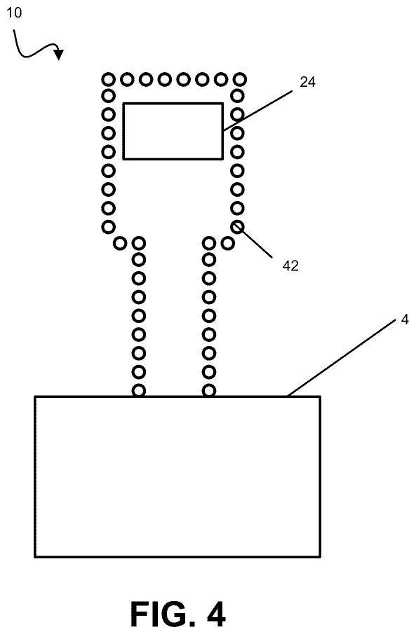

Referring now to FIG. 4 an example of an RF port 10 will be described. The RF port 10 comprises a substrate integrated waveguide 42 which is configured to transfer the RF signal from a semiconductor chip 4 into an opening 24 of the printed circuit board 12. The substrate integrated waveguide 42 may use a launcher integrated into the redistribution layer 8 of the associated semiconductor circuit device to provide the coupling from the substrate integrated waveguide 42 via the opening 24 of the printed circuit board 12 to the respective waveguide port. In other examples a launcher may be integrated into or arranged on the printed circuit board 12 in order to provide the coupling from to the respective waveguide port. In some examples the launcher may be configured to receive the RF signals from the semiconductor chip 4 with an essential lateral transmission direction and may be configured to transfer the same into RF signals having an essential vertical transmission direction in order to allow an efficient transmission of the RF signals to a vertical part of the hollow waveguide. Similar RF ports may be provided to implement RF ports configured to receive signals from a respective hollow waveguide. The same RF ports may be used for transferring LO signals and for transferring RF transmit or receive signals as both utilize the same frequencies or may be located in the same frequency range.

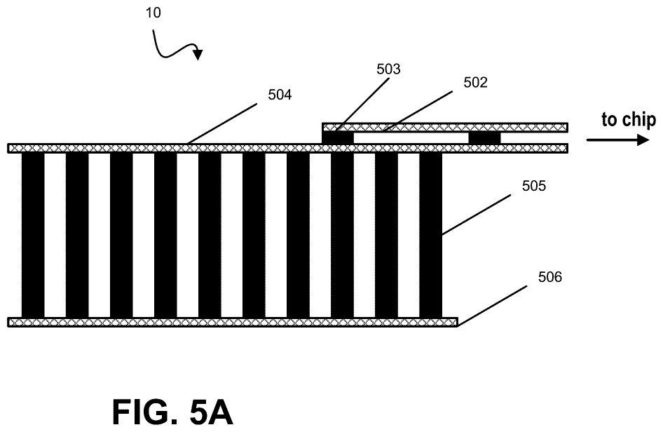

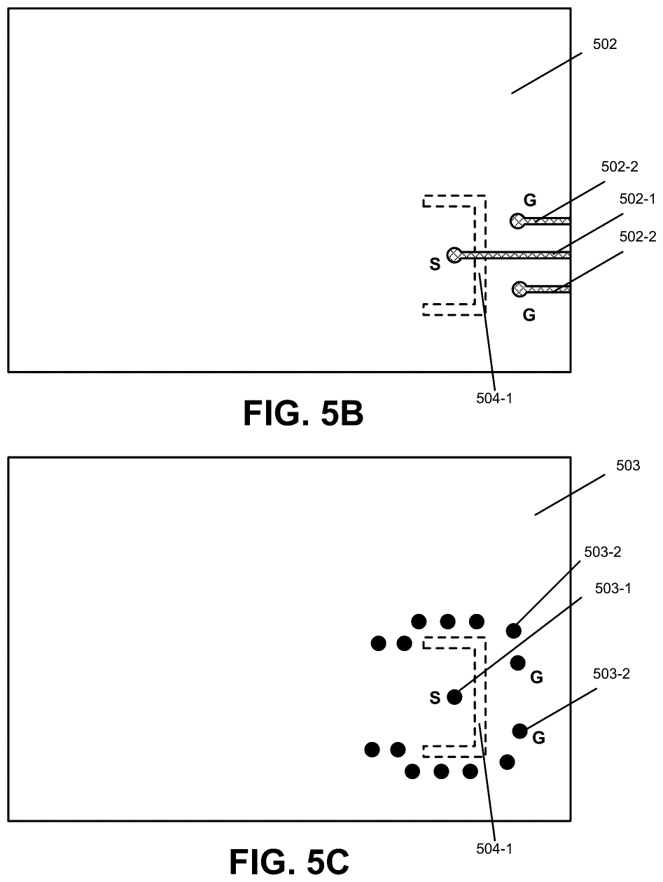

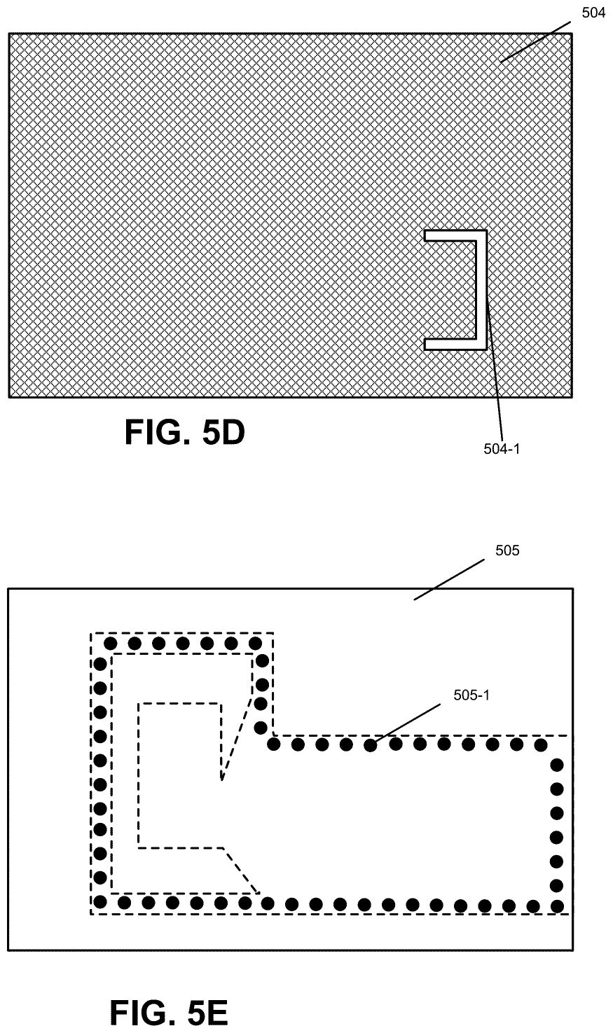

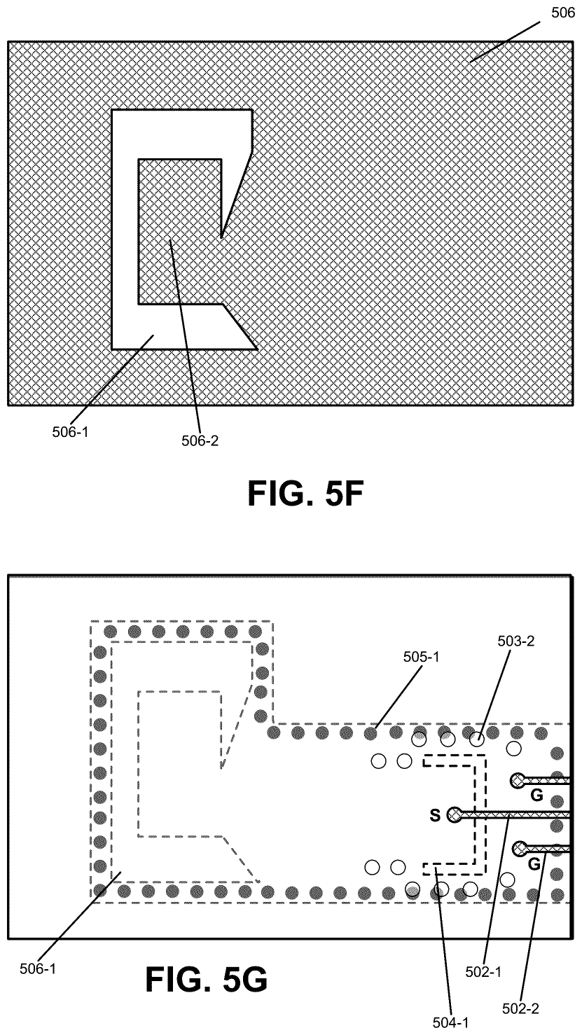

A further example of an RF port 10 is shown in detail in FIGS. 5A to 5G. FIG. 5A shows a lateral view of a portion of a redistribution layer of a semiconductor circuit device (for example the first semiconductor circuit device 2-1 or the second semiconductor circuit device 2-2). A first layer 502 is in a vertical direction the layer closest to the chip level. The first layer 502 comprises signal lines and ground lines which are connected through vias arranged in a second layer 503 to a third layer 504. The signal lines and ground lines may form a planar waveguide to transmit the RF signal. The third layer 504 forms a top part of a substrate integrated waveguide and is connected to a fifth layer 506 through vias arranged in a fourth layer 505. The fifth layer 506 forms a lower part of the substrate integrated waveguide.

FIG. 5B shows a top view of the first layer 502. In the first layer 502 a signal line 502-1 is formed which extends over and crosses a region 504-1 associated with a gap (opening) in the third layer 504 as will be explained later. The signal line 502-1 is connected at one end to a signal line of the semiconductor chip 4. The first layer 502 further includes ground lines 502-2 which are connected to ground potential. As can be seen the ground lines 502-2 do not extend in the region 504-1 and do not cross the region 504-1. The signal lines 502-1 and the ground lines 502-2 are metal lines and form an RF planar waveguide. For coupling the RF signals into the substrate integrated waveguide, the signal line 502-1 is electrically connected to a via 503-1 and the ground lines 502-2 are electrically connected to respective vias of a plurality of vias 503-2 shown in FIG. 5C. Vias 503-1 and 503-2 provide an electrical connection in the vertical direction from the first layer 502 to the third layer 504 to excite a current in the third layer 504 allowing the RF coupling into the substrate integrated waveguide.

FIG. 5D shows the third layer 504 formed as a continuous metal layer having a gap in the region 504-1. Since the signal line 502-1 crosses the region 504-1 while the ground line 502-2 does not cross the region 504-1, AC currents are excited in the third layer 504 flowing around the gap region 504-1. Since the third layer 504 is the top plate of the substrate integrated waveguide, the AC currents excite an RF signal in the substrate integrated waveguide. In FIG. 5D, the opening is shown as a slot in rectangular U-form, however other shapes such as a straight slot, a V-shaped slot or a semi-circular slot are also possible. Compared to a straight slot, a U-shaped, V-shaped or semi-circular slot reduces the dimension in a lateral direction increasing the design flexibility and allowing to implement more RF ports on a specific area.

The third layer 504 is connected to the fifth layer 506 acting as a bottom plate of the substrate integrated waveguide by vias 505-1 arranged in the layer 505. FIG. 5E shows the vias 505-1 defining a lateral boundary of the substrate integrated waveguide. FIG. 5F shows the fifth layer 506 as a continuous metal layer having an opening 506-1 to define a launcher 506-2.

The launcher 506-2 provides a vertical RF coupling to a respective opening in the printed circuit board 12 and a respective waveguide port to excite an RF signal transmission in the hollow waveguide below the launcher.

FIG. 5G shows a transparent top view of the structures in the layers 502 to 506 as described above forming the RF port. In case the RF port is a transmit RF port, the substrate integrated waveguide is formed with structures to couple the RF signals from the planar waveguide into the substrate integrated waveguide and with a launcher to couple the RF signal from the substrate integrated waveguide into the opening of the printed circuit board 12. In case the RF port is a receive RF port, the substrate integrated waveguide is formed with a launcher to couple the RF signal from the opening of the printed circuit board 12 into the substrate integrated waveguide and with structures to couple the RF signals from the substrate integrated waveguide into the planar waveguide.

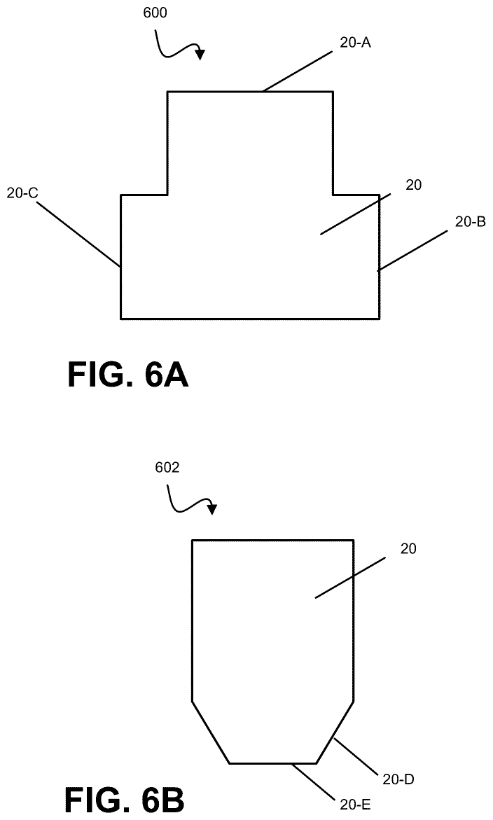

Referring now to FIGS. 6A and 6B, functional structures provided in the hollow waveguides of the waveguide antenna will be described.

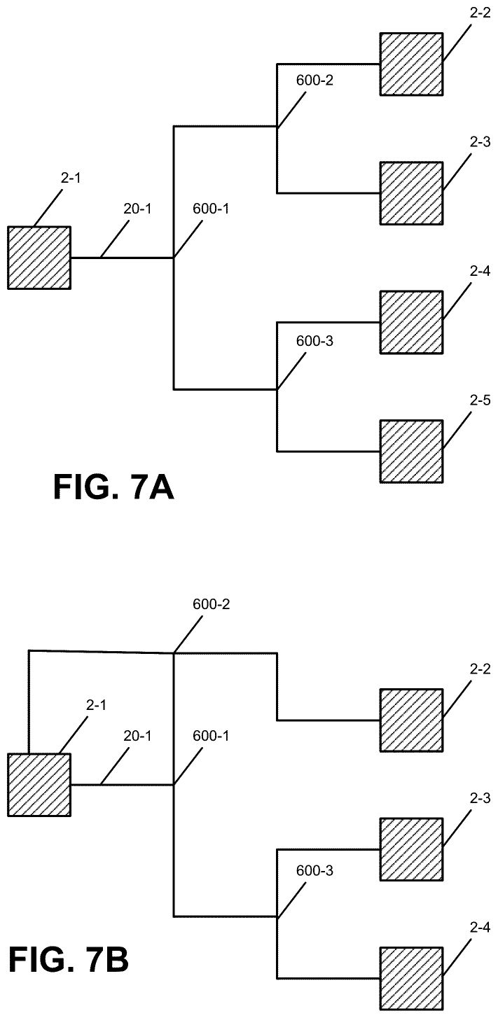

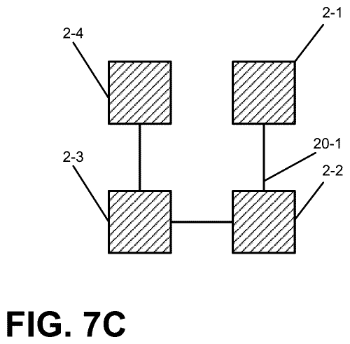

FIG. 6A shows a splitter element 600 as a functional element which may be implemented in a waveguide 20. The splitter element 600 comprises a first splitter port 20-A a second splitter port 20-B and a third splitter port 20-C. The first splitter port 20-A is a receive port configured to receive RF signals from a first portion of the waveguide 20. The splitter 600 is configured to split the RF signal into a first RF signal portion and a second RF signal portion which are transmitted via the second splitter port 20-B and the third splitter port 20-C to respective waveguide portions of the waveguide 20. The splitting may be symmetric such that the first RF signal portion and a second RF signal portion have a same amount of power. The splitter described above may be used for example in the example of FIGS. 2A and 2B implementing a LO distribution with self-feeding. Furthermore, the splitter may be used in the examples described below with respect to FIGS. 7A and 7B.

FIG. 6B shows an adaption element 602 as a further functional element which may be implemented in a hollow waveguide 20. The adaption element 602 includes a section 20-D in which for example a waveguide form or a waveguide cross-section area is varied in order to modify RF signals output or received via a port 20-E. The adaption element 602 may for example be used at the waveguide ports 22-1, 22-2, 22-3, 22-4 described in the above examples for coupling the RF signals into the openings 24-1, 24-2, 24-3, 24-4 or to receive the RF signals form the openings 24-1, 24-2, 24-3, 24-4. This may increase the coupling efficiency and may reduce losses of the RF signals.

Referring now to FIGS. 7A to 7C, examples of an LO signal distribution implemented in the RF modules, for example RF modules 100, 200 and 300 are described. FIG. 7A shows an example of a symmetric LO signal distribution from the first semiconductor circuit device 2-1 to the semiconductor circuit devices 2-2, 2-3, 2-4 and 2-5. The first hollow waveguide 20-1 is split using a first splitter 600-1 into two hollow waveguide sections. Each of the hollow waveguide sections are further split using splitters 600-2 and 600-3. The first hollow waveguide couples the RF port of the first semiconductor circuit device 2-1 distributing the LO signal with the respective RF ports of the semiconductor circuit devices 2-2, 2-3, 2-4 and 2-5 receiving the LO signal. The length of the waveguide sections between the first semiconductor circuit device 2-1 and each of the semiconductor circuit devices 2-2, 2-3, 2-4 and 2-5 are the same making the LO signal distribution symmetric and phases of the LO signals received at the semiconductor circuit devices 2-2, 2-3, 2-4 and 2-5 are the same.

FIG. 7B shows an example of a LO signal distribution from the first semiconductor circuit device 2-1 to the to the semiconductor circuit devices 2-2, 2-3 and 2-4 with self-feeding. The first hollow waveguide 20-1 is split using a first splitter 600-1 into two hollow waveguide sections. Each of the hollow waveguide sections are further split using splitters 600-2 and 600-3 into further hollow waveguide sections. One of the further hollow waveguide sections coupled to the splitter 600-2 is coupled to an RF port of the second semiconductor circuit device 2-2 while one of the further hollow waveguide sections coupled to the splitter 600-2 is coupled back to an input RF port of the first semiconductor circuit device 2-1. In operation, the first semiconductor circuit device 2-1 uses the LO signal fed back for processing such as generating transmit signals or mixing received signals. Furthermore the further hollow waveguide sections coupled to the splitter 600-3 are coupled to RF ports of the semiconductor circuit devices 2-3 and 2-4, respectively. The length of the waveguide sections between the first semiconductor circuit device 2-1 and the input RF port of the first semiconductor circuit device 2-1 is the same as the length of the waveguide sections between the first semiconductor circuit device 2-1 and each of the semiconductor circuit devices 2-2, 2-3 and 2-4 making the LO signal distribution symmetric and phases of the LO signals received at the semiconductor circuit devices 2-1, 2-2, 2-3 and 2-4 are the same. The LO distribution to the plurality of semiconductor circuit devices 2-2, 2-3 and 2-4 including the feed back to the first semiconductor circuit device 2-1 allows to obtain stability of the phases of the LO signals that are processed by the semiconductor circuit devices 2-1, 2-2, 2-3 and 2-4 allowing using the semiconductor circuit devices 2-1, 2-2, 2-3 and 2-4 in a MIMO operation for transmitting and receiving signals.

A further example of LO signal distribution is shown in FIG. 7C. FIG. 7C shows the LO distribution in a daisy chain configuration. An RF port of the first semiconductor circuit device 2-1 is coupled to a first part of the first hollow waveguide 20-1 to couple the LO signal into the first hollow waveguide 20-1. The LO signal is received at an input RF port of the second semiconductor circuit device 2-2 and transferred to a second part of the first hollow waveguide 20-1. The LO signal is received at an input RF port of the third semiconductor circuit device 2-3 and transferred to a third part of the first hollow waveguide 20-1. The LO signal is received from the third part of the first hollow waveguide 20-1 at an input RF port of the fourth semiconductor circuit device 2-4. In this example, the LO signals received at the semiconductor circuit devices 2-2, 2-3 and 2-4 have different phases and the phase differences may change with temperature. A compensation or calibration technique may be applied to address phase changes resulting from temperature variations in order to establish MIMO operation.

In the above, various examples of an RF module have been described utilizing a waveguide antenna with hollow waveguides formed in the interior of a body of the waveguide antenna. The hollow waveguides are used for transmission of transmit signals and receive signals between the antenna elements of the waveguide antenna and multiple semiconductor circuit devices as well as for LO signal distribution between the multiple semiconductor circuit devices. This allows an easy and cost-efficient implementation of an RF module, for example for MIMO operations, avoiding the routing of LO signals on a printed circuit board.

### Aspects

In addition to the above described aspects, the following aspects are disclosed herein.

Aspect 1 is an RF module comprising: a circuit board comprising a plurality of signal lines, a waveguide antenna arranged on a first side of the circuit board, the waveguide antenna comprising a body, an antenna element formed in the body, a first hollow waveguide formed in the body, and a second hollow waveguide formed in the body, wherein the second hollow waveguide is coupled to the antenna element, a first semiconductor circuit device arranged on a second side of the printed circuit board and electrically connected to a first signal line of the plurality of signal lines, a second semiconductor circuit device arranged on the second side of the printed circuit board and electrically connected to a second signal line of the plurality of signal lines, wherein the RF module comprises a first RF port associated with the first semiconductor circuit device, wherein the first semiconductor circuit device comprises a local oscillator to generate a local oscillator signal, wherein the circuit board comprises a first opening between the first RF port and a first waveguide port associated with the first hollow waveguide for transferring the local oscillator signal from the first RF port into the first hollow waveguide; wherein the RF module comprises a second RF port associated with the second semiconductor circuit device, wherein the circuit board comprises a second opening between the second RF port and a second waveguide port associated with the first waveguide to receive the local oscillator signal from the first hollow waveguide, wherein the second semiconductor circuit device is configured to process a first RF signal based on the received local oscillator signal, wherein the RF module comprises a third RF port associated with the second semiconductor circuit device and wherein the circuit board comprises a third opening for transferring the first RF signal between the third RF port and a third waveguide port associated with the second hollow waveguide.

Aspect 2 is the RF module of Aspect 1, wherein first RF signal is an RF transmit signal and wherein the second semiconductor circuit device is configured to generate the RF transmit signal based on the received local oscillator signal, wherein the third RF port comprises a launcher to transfer the RF transmit signal via the third opening to the first waveguide port for transmitting via the antenna element.

Aspect 3 is the RF module of Aspect 1, wherein the first RF signal is an RF receive signal received by the antenna element and wherein the third RF port comprises a launcher to receive the RF receive signal from the second hollow waveguide via the third opening and wherein the second semiconductor circuit device is configured to down-convert the RF receive signal using the received local oscillator signal.

Aspect 4 is the RF module of Aspects 2 and 3, wherein the launcher is integrated into the second semiconductor circuit device.

Aspect 5 is the RF module of any of the preceding aspects, wherein the first semiconductor circuit device and the second semiconductor circuit device comprise a redistribution layer, mold material defining a fan-out area and wherein at least one of the second RF port or third RF port is arranged in the fan-out area.

Aspect 6 is the RF module of any of the preceding aspects, wherein the RF module comprises a fourth RF port associated with the first semiconductor circuit device and wherein the circuit board comprises a fourth opening between the fourth RF port and a fourth waveguide port associated with the first hollow waveguide, wherein the first hollow waveguide comprises a splitter for splitting the local oscillator signal into a first part transferred to the second RF port and a second part transferred to the fourth RF port.

Aspect 7 is the RF module of any of the preceding aspects, wherein the first semiconductor circuit device is a primary monolithic microwave integrated device and wherein the second semiconductor circuit device is a secondary monolithic microwave integrated circuit device, wherein the first monolithic microwave integrated circuit device comprises a first plurality of RF channels and wherein the secondary monolithic microwave integrated circuit device comprises a second plurality of RF channels, wherein the secondary monolithic microwave integrated circuit device is configured to synchronize the second plurality of RF channels to the first plurality of RF channels using the received local oscillator signal.

Aspect 8 is the RF module of any of the preceding aspects, wherein the body comprises body parts which are mounted together.

Aspect 9 is the RF module of any of the preceding aspects, wherein the body comprises plastic material and wherein the first hollow waveguide and the second hollow waveguide comprise metal layers which are formed on walls of openings in the body.

Aspect 10 is the RF module of any of the preceding aspects, wherein the antenna element comprises a plurality of slits formed on an outer surface of the body.

Aspect 11 is the RF module of any of the preceding aspects, wherein the RF module further comprises at least one of a power supply arranged on the circuit board or a processing device arranged on the circuit board.

Aspect 12 is the RF module of any of the preceding aspects, wherein each of the first waveguide port, the second waveguide port and the third waveguide port comprise a transmission adaption element to adapt the transmission characteristics for coupling with the first opening, second opening and third opening, respectively.

Aspect 13 is the RF module of Aspect 12, wherein the transmission adaption element comprises a varying waveguide portion, the varying waveguide portion comprising at least one of: a varying waveguide form, or a varying waveguide cross-section.

Aspect 14 is the RF module of any of the preceding aspects, wherein the first semiconductor circuit device and the second semiconductor circuit device are FMCW radar devices and wherein the local oscillator signal comprises a plurality of frequency-modulated radar chirps.

Aspect 15 is the RF module of any of the preceding aspects, wherein the first hollow waveguide comprises a first portion extending perpendicular to a main surface of the circuit board and a second portion extending parallel to a main surface of the circuit board and wherein the second hollow waveguide comprises a third portion extending perpendicular to a main surface of the circuit board and a fourth portion extending parallel to a main surface of the circuit board.

Aspect 16 is the RF module of Aspect 15, wherein the second portion is closer to the circuit board than the fourth portion.

Aspect 17 is the RF module of any of the preceding aspects, wherein the second semiconductor circuit device comprises a semiconductor package, the semiconductor package comprising a redistribution layer, wherein the third RF port comprises a substrate integrated waveguide structure which is formed by a first metal layer of the redistribution layer, a second metal layer of the redistribution layer and a plurality of vertical metal structures formed between the first metal layer and the second metal layer.

Aspect 18 is the RF module of Aspect 17, wherein the redistribution layer comprises a third metal layer, wherein the third metal extends over a gap in the second metal layer.

Aspect 19 is the RF module of any of the preceding aspects, wherein the RF module comprises a launcher associated with at least one of the first RF port, second RF port or the third RF port, wherein the launcher is integrated in the circuit board or arranged on the circuit board.

Although specific aspects have been illustrated and described herein, it will be appreciated by those of ordinary skill in the art that a variety of alternate and/or equivalent implementations may be substituted for the specific aspects shown and described without departing from the scope of the present implementation. This application is intended to cover any adaptations or variations of the specific aspects discussed herein. Therefore, it is intended that this implementation be limited only by the claims and the equivalents thereof.

It should be noted that the methods and devices including its preferred implementations as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the implementation and are included within its spirit and scope. Furthermore, all aspects and implementations outlined in the present document are principally intended expressly to be only for explanatory purposes to help the reader in understanding the principles of the proposed methods and systems. Furthermore, all statements herein providing principles, aspects, and implementations of the implementation, as well as specific aspects thereof, are intended to encompass equivalents thereof.

1. An RF module comprising:
a circuit board comprising a plurality of signal lines;
a waveguide antenna arranged on a first side of the circuit board, the waveguide antenna comprising a body, an antenna element formed in the body, a first hollow waveguide formed in the body, and a second hollow waveguide formed in the body, wherein the second hollow waveguide is coupled to the antenna element;
a first semiconductor circuit device arranged on a second side of the circuit board and electrically connected to a first signal line of the plurality of signal lines;
a second semiconductor circuit device arranged on the second side of the circuit board and electrically connected to a second signal line of the plurality of signal lines;
a first RF port associated with the first semiconductor circuit device, wherein the first semiconductor circuit device comprises a local oscillator to generate a local oscillator signal, wherein the circuit board comprises a first opening between the first RF port and a first waveguide port associated with the first hollow waveguide for transferring the local oscillator signal from the first RF port into the first hollow waveguide;
a second RF port associated with the second semiconductor circuit device, wherein the circuit board comprises a second opening between the second RF port and a second waveguide port associated with the first hollow waveguide to receive the local oscillator signal from the first hollow waveguide, wherein the second semiconductor circuit device is configured to process a first RF signal based on the received local oscillator signal; and
a third RF port associated with the second semiconductor circuit device and wherein the circuit board comprises a third opening for transferring the first RF signal between the third RF port and a third waveguide port associated with the second hollow waveguide.

2. The RF module of claim 1, wherein first RF signal is an RF transmit signal,
wherein the second semiconductor circuit device is configured to generate the RF transmit signal based on the received local oscillator signal, and
wherein the third RF port comprises a launcher to transfer the RF transmit signal via the third opening to the first waveguide port for transmitting via the antenna element.

3. The RF module of claim 1, wherein the first RF signal is an RF receive signal received by the antenna element,
wherein the third RF port comprises a launcher to receive the RF receive signal from the second hollow waveguide via the third opening, and
wherein the second semiconductor circuit device is configured to down-convert the RF receive signal using the received local oscillator signal.

4. The RF module of claim 2, wherein the launcher is integrated into the second semiconductor circuit device.

5. The RF module of claim 1, wherein the first semiconductor circuit device and the second semiconductor circuit device each comprise a redistribution layer and mold material defining a respective fan-out area, and
wherein at least one of the second RF port or third RF port is arranged in the respective fan-out area.

6. The RF module of claim 1,
wherein the RF module further comprises;
a fourth RF port associated with the first semiconductor circuit device,
wherein the circuit board comprises a fourth opening between the fourth RF port and a fourth waveguide port associated with the first hollow waveguide, and
wherein the first hollow waveguide comprises a splitter for splitting the local oscillator signal into a first part transferred to the second RF port and a second part transferred to the fourth RF port.

7. The RF module of claim 1,
wherein the first semiconductor circuit device is a primary monolithic microwave integrated circuit device and the second semiconductor circuit device is a secondary monolithic microwave integrated circuit device,
wherein the first monolithic microwave integrated circuit device comprises a first plurality of RF channels and the secondary monolithic microwave integrated circuit device comprises a second plurality of RF channels, and
wherein the secondary monolithic microwave integrated circuit device is configured to synchronize the second plurality of RF channels to the first plurality of RF channels using the received local oscillator signal.

8. The RF module of claim 1, wherein the body comprises body parts which are mounted together.

9. The RF module of claim 1, wherein the body comprises plastic material, and
wherein the first hollow waveguide and the second hollow waveguide comprise metal layers which are formed on walls of openings in the body.

10. The RF module of claim 1, wherein the antenna element comprises a plurality of slits formed on an outer surface of the body.

11. The RF module of claim 1, wherein the RF module further comprises at least one of:
a power supply arranged on the circuit board, or
a processing device arranged on the circuit board.

12. The RF module of claim 1, wherein each of the first waveguide port, the second waveguide port, and the third waveguide port comprise a respective transmission adaption element to adapt transmission characteristics for coupling with the first opening, the second opening, and the third opening, respectively.

13. The RF module of claim 12, wherein the respective transmission adaption element comprises a varying waveguide portion, the varying waveguide portion comprising at least one of:
a varying waveguide form, or
a varying waveguide cross-section.

14. The RF module of claim 1, wherein the first semiconductor circuit device and the second semiconductor circuit device are FMCW radar devices, and
wherein the local oscillator signal comprises a plurality of frequency-modulated radar chirps.

15. The RF module of claim 1, wherein the first hollow waveguide comprises a first portion extending perpendicular to a main surface of the circuit board and a second portion extending parallel to the main surface of the circuit board, and
wherein the second hollow waveguide comprises a third portion extending perpendicular to the main surface of the circuit board and a fourth portion extending parallel to the main surface of the circuit board.

16. The RF module of claim 15, wherein the second portion is closer to the circuit board than the fourth portion.

17. The RF module of claim 1, wherein the second semiconductor circuit device comprises a semiconductor package, the semiconductor package comprising a redistribution layer, and
wherein the third RF port comprises a substrate integrated waveguide structure which is formed by a first metal layer of the redistribution layer, a second metal layer of the redistribution layer, and a plurality of vertical metal structures formed between the first metal layer and the second metal layer.

18. The RF module of claim 17, wherein the redistribution layer comprises a third metal layer, and
wherein the third metal layer extends over a gap in the second metal layer.

19. The RF module of claim 1,
wherein the RF module comprises a launcher associated with at least one of the first RF port, the second RF port, or the third RF port,
wherein the launcher is integrated in the circuit board or arranged on the circuit board.

20. An RF module comprising:
a circuit board;
a waveguide antenna comprising:
a body,
an antenna element,
a first hollow waveguide, and
a second hollow waveguide coupled to the antenna element;
a first semiconductor circuit device electrically coupled to the circuit board, the first semiconductor circuit device comprising:
a local oscillator configured to generate a local oscillator signal, wherein a first waveguide port is configured to transfer the local oscillator signal from a first RF port and into the first hollow waveguide via a first opening formed in the circuit board; and
a second semiconductor circuit device electrically coupled to the circuit board, wherein the second semiconductor circuit device is configured to:
receive the local oscillator signal via the first hollow waveguide,
process a first RF signal based on the local oscillator signal, and
transfer the first RF signal to the antenna element via the second hollow waveguide.
